(19) United States
(12) Patent Application Publication
(10) Pub. No.: US 2024/0213766 A1
(43) Pub. Date: Jun. 27, 2024

(54) CIRCUIT-BREAKER, CIRCUIT-BREAKER ABNORMALITY DIAGNOSIS METHOD, AND LITHIUM BATTERY SYSTEM

(71) Applicants: Camel Group Wuhan Optics Valley R&D Center Co., Ltd., Wuhan (CN); Camel Group Co., Ltd., Xiangyang (CN)

(72) Inventors: Junlin LI, Wuhan (CN); Changlai LIU, Wuhan (CN); Shizhong XIA, Wuhan (CN); Huan JIANG, Wuhan (CN); Nian CHEN, Wuhan (CN); Che LIU, Wuhan (CN)

(21) Appl. No.: 18/598,714

(22) Filed: Mar. 7, 2024

Related U.S. Application Data
(63) Continuation of application No. PCT/CN2022/088805, filed on Apr. 24, 2022.

(30) Foreign Application Priority Data
Mar. 1, 2022 (CN) 202210193625.9

(51) Int. Cl. H02H 7/18; G01R 31/327; H01M 50/574; H03K 17/687

(52) U.S. Cl. CPC H02H 7/18; G01R 31/3274; H01M 50/574; H03K 17/6871; H01M 2200/00

(57) ABSTRACT

A circuit-breaker includes a battery module terminal, a battery pack system terminal, and a plurality of switching channels connected in parallel and coupled between the battery module terminal and the battery pack system terminal. Each of the switching channels includes one or more semiconductor switching devices and is configured to turn on/off a circuit between the battery module terminal and the battery pack system terminal. During abnormality diagnosis, at least one of the switching channels is set to be in a turned-on state.

### CROSS-REFERENCE TO RELATED APPLICATIONS

This application is a continuation of International Application No. PCT/CN2022/088805, filed on Apr. 24, 2022, which claims priority to Chinese Patent Application No. 202210193625.9, filed on Mar. 1, 2022. The disclosures of the aforementioned applications are incorporated herein by reference in their entireties.

### TECHNICAL FIELD

The present disclosure relates to electrical technologies, and in particular, to a circuit-breaker, a circuit-breaker abnormality diagnosis method, and a lithium battery system.

### BACKGROUND

With the development of the new energy vehicle industry, new energy vehicles using lithium batteries as energy storage devices have become popular. In conventional lithium battery system designs, a relay is often used as the preferred component of a circuit-breaker for a main circuit of the battery system.

However, the relay has a slow action switching response (greater than 10 ms), which is not conducive to short-circuit protection. The life of contacts of the relay will be greatly shortened in the case of arcing. In addition, mechanical noise generated by mechanical state switching at the moment the relay is turned on or off may cause bad user experience. Thus, in the application of high-end lithium battery systems, especially in the application of low-voltage lithium battery systems of 12 V, 24 V, 48 V or the like, a design of using a semiconductor switching device as a circuit-breaker for a main circuit has become popular.

A power metal-oxide-semiconductor field-effect transistor (MOSFET) has many advantages such as low cost, small size, light weight, low on-resistance, simple layout, and the like. Thus, in the related art, a MOSFET is usually used as a preferred semiconductor switching circuit-breaker. However, when a semiconductor switching device is used as a circuit-breaker in a lithium battery system, it is impossible to quickly and accurately diagnose an abnormality state of the semiconductor switching device if the circuit-breaker is abnormal, and it is not convenient to check the aging degree of the circuit-breaker on a daily basis.

### SUMMARY

According to one or more embodiments of the present disclosure, a circuit-breaker includes a battery module terminal, a battery pack system terminal, and N switching channels connected in parallel and coupled between the battery module terminal and the battery pack system terminal, where N is a positive integer greater than or equal to 2. Each of the switching channels includes one or more semiconductor switching devices and is configured to turn on/off a circuit between the battery module terminal and the battery pack system terminal. When abnormality diagnosis is performed on the N switching channels, at least one of the N switching channels is set to be in a turned-on state to keep the circuit-breaker in a turned-on state.

According to one or more embodiments of the present disclosure, a circuit-breaker abnormality diagnosis method applicable to the above circuit-breaker includes: setting at least one of the N switching channels to be in the turned-on state; obtaining at a current moment a first voltage value at an input potential node, a second voltage value at an output potential node, and N third voltage values respectively at N channel potential nodes corresponding to the N switching channels; and performing abnormality diagnosis on the semiconductor switching devices in the N switching channels based on the first voltage value, the second voltage value, and the N third voltage values, to obtain a switching device abnormality diagnosis result.

According to one or more embodiments of the present disclosure, a lithium battery system includes the above circuit-breaker.

### BRIEF DESCRIPTION OF THE DRAWINGS

FIG. 1 is a schematic diagram of an exemplary structure of a circuit-breaker according to one or more embodiments of the present disclosure.

FIG. 2 is a schematic diagram of an exemplary structure of a circuit-breaker according to one or more embodiments of the present disclosure.

FIG. 3 is a schematic diagram of an exemplary structure of a circuit-breaker according to one or more embodiments of the present disclosure.

FIG. 4 is an exemplary flowchart of a circuit-breaker abnormality diagnosis method according to one or more embodiments of the present disclosure.

FIG. 5 is an exemplary flowchart of a circuit-breaker abnormality diagnosis method according to one or more embodiments of the present disclosure.

FIG. 6 is a block diagram of a lithium battery system including a circuit-breaker according to one or more embodiments of the present disclosure.

### DETAILED DESCRIPTION

Some embodiments of the present disclosure will be described in detail below with reference to the accompanying drawings. The embodiments are described for illustrative purposes only and are not intended to limit the present disclosure.

It should be understood that, in the description of one or more embodiments of the present disclosure, the terms “first” and “second” are merely for illustrative purposes and should not be construed as indicating or implying the relative importance or implicitly indicating the number of technical features. Therefore, a feature defined by “first” or “second” may explicitly or implicitly include one or more such features. The term “a plurality of” means two or more, unless otherwise specifically defined.

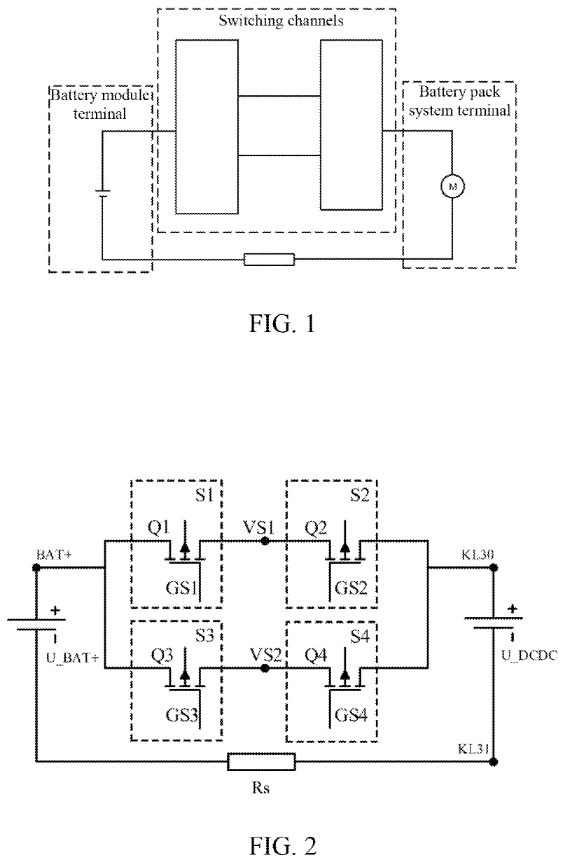

FIG. 1 is a schematic diagram of an exemplary structure of a circuit-breaker according to one or more embodiments of the present disclosure. As shown in FIG. 1, the circuit-breaker includes a battery module terminal, a battery pack system terminal, and N switching channels that are connected in parallel and coupled between the battery module terminal and the battery pack system terminal, where N is a positive integer greater than or equal to 2. Each of the switching channels includes one or more semiconductor switching devices, and is configured to turn on/off a circuit between the battery module terminal and the battery pack system terminal. When abnormality diagnosis is performed on the N switching channels, at least one of the N switching channels is set to be in a turned-on state to keep the circuit-breaker in a turned-on state.

In one or more embodiments of the present disclosure, one or more semiconductor switching devices constitute a switching channel of a circuit-breaker. Compared with the conventional method of using a relay in a circuit-breaker, the embodiments of the present disclosure can effectively avoid problems of the relay such as on-load disconnection, mechanical noise pollution, and easily damaged relay contacts, and have the advantages such as fast action response, high integration, and small electrical volume.

In addition, the circuit-breaker according to one or more embodiments of the present disclosure includes a plurality of switching channels connected in parallel. Thus, when the circuit-breaker is applied to a battery system or another device and a fault occurs in the circuit-breaker, the circuit-breaker can be kept in a turned-on state by controlling at least one of the N switching channels to be in the turned-on state. For example, when the circuit-breaker is applied to a vehicle-mounted low-voltage power supply, it can be ensured that a battery pack is always connected to a vehicle-mounted low-voltage power supply network, so that abnormality diagnosis can be performed on switching channels of the circuit-breaker to determine a semiconductor switching device in the switching channels with an abnormality of aging or being uncontrolled, thereby allowing for timely detection and diagnosis of a fault and having higher safety.

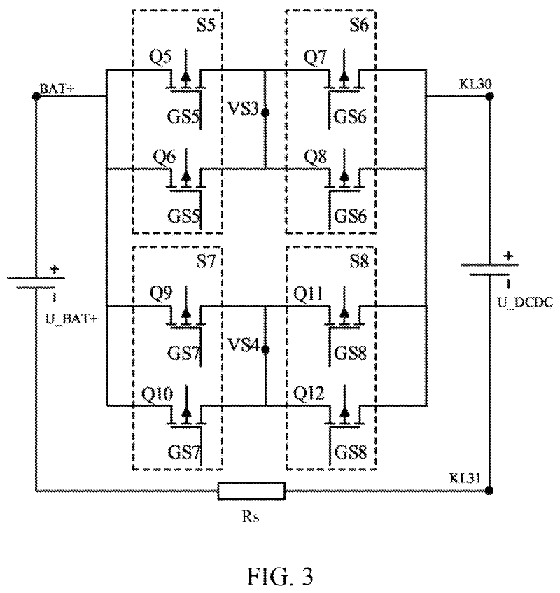

In one or more embodiments, N is a positive integer greater than or equal to 2. That is, N may be 2, 3, 4, etc. For example, as shown in FIG. 2 and FIG. 3, the circuit-breaker may include 2 switching channels. The number of switching channels in the circuit-breaker may be set according to the requirements.

In addition, if the circuit-breaker according to one or more embodiments of the present disclosure is applied to a battery system, the battery system may be configured to include a plurality of such circuit-breakers connected in parallel, thereby enhancing an overcurrent capability of the battery system.

In one or more embodiments of the present disclosure, each switching channel includes: a first switch group coupled to the battery module terminal; and a second switch group coupled to the first switch group and the battery pack system terminal. A coupling node between the first switch group and the second switch group serves as a channel potential node, an input potential node is formed between the first switch group and the battery module terminal, and an output potential node is formed between the second switch group and the battery pack system terminal.

In application of the circuit-breaker, the first switch group and the second switch group in the switching channel can be used to jointly control connection/disconnection between the battery module terminal and the battery pack system terminal of the circuit-breaker. During the operation of the circuit-breaker, respective voltages at the input potential node, the channel potential node, and the output potential node may be detected to diagnose an abnormality of semiconductor switching devices in the circuit-breaker.

As shown in FIG. 2 and FIG. 3, the first switch group and the second switch group each may include at least one switching transistor. One or more switching transistors in the first switch group respectively correspond to one or more switching transistors in the second switch group. For example, when the first switch group includes two switching transistors, the second switch group also includes two switching transistors that respectively correspond to the two switching transistors in the first switch group. Each of the switching transistors in the first switch group and the second switch group may be a transistor, a MOSFET, a thyristor, or another device have a switching function. In examples of the present disclosure as shown in FIG. 2 and FIG. 3, each switching transistor in the first switch group and the second switch group is a MOSFET.

In one or more embodiments of the present disclosure, as shown in FIG. 2, the circuit-breaker includes two switching channels. Each of the first switch group and the second switch group in each switching channel includes one switching transistor. The circuit-breaker further includes a first drive terminal and a second drive terminal. The first switch group includes a first switching transistor having a first control electrode coupled to the first drive terminal. The second switch group includes a second switching transistor having a second control electrode coupled to the second drive terminal.

Specifically, one of the switching channels includes switch group S1 as the first switch group and switch group S2 as the second switch group. Switch group S1 as the first switch group serves as a charge enable MOSFET group, and switch group S2 as the second switch group serves as a discharge enable MOSFET group. Switch group S1 as the first switch group includes switching transistor Q1, as the first switching transistor, having a gate as the first control electrode. Switch group S2 as the second switch group includes switching transistor Q2, as the second switching transistor, having a gate as the second control electrode. The gate of switching transistor Q1 is coupled to drive terminal GS1 as the first drive terminal, and the gate of switching transistor Q2 is coupled to drive terminal GS2 as the second drive terminal.

In application, switching transistor Q1 can be controlled to be turned on or off by changing a level of drive terminal GS1, and switching transistor Q2 can be controlled to be turned on or off by changing a level of drive terminal GS2, thereby controlling the switching channel to be turned on or off.

Similarly, switch group S3 as the first switch group and switch group S4 as the second switch group constitute the other switching channel. Switch group S3 as the first switch group has the same function as switch group S1 as the first switch group, and switch group S4 as the second switch group has the same function as switch group S2 as the second switch group. That is, switch group S3 serves as a charge enable MOSFET group, and switch group S4 serves as a discharge enable MOSFET group. Switch group S3 as the first switch group includes switching transistor Q3, as the first switching transistor, having a gate as the first control electrode. Switch group S4 as the second switch group includes switching transistor Q4, as the second switching transistor, having a gate as the second control electrode. The gate of switching transistor Q3 is coupled to drive terminal GS3 as the first drive terminal, and the gate of the second switching transistor Q4 is coupled to drive terminal GS4 as the second drive terminal.

In application, switching transistor Q3 can be controlled to be turned on or off by changing a level of drive terminal GS3, and switching transistor Q4 can be controlled to be turned on or off by changing a level of drive terminal GS4, thereby controlling the switching channel to be turned on or off.

In one or more embodiments of the present disclosure, as shown in FIG. 2, the circuit-breaker includes two switching channels. Each of the first switch group and the second switch group in each switching channel includes one switching transistor. The first switching transistor has a first primary voltage electrode and a first secondary voltage electrode. The second switching transistor has a second primary voltage electrode and a second secondary voltage electrode.

The first primary voltage electrode of the first switching transistor is coupled to the second primary voltage electrode of the second switching transistor, and a first channel potential node as the channel potential node is formed between the first primary voltage electrode and the second primary voltage electrode. The first secondary voltage electrode of the first switching transistor is coupled to the battery module terminal, and a first input potential node as the input potential node is formed between the first secondary voltage electrode and the battery module terminal. The second secondary voltage electrode of the second switching transistor is coupled to the battery pack system terminal, and a first output potential node as the output potential node is formed between the second secondary voltage electrode and the battery pack system terminal.

In one or more embodiments, the first switching transistor has the first primary voltage electrode and the first secondary voltage electrode, and each of the first primary voltage electrode and the first secondary voltage electrode may be a source or drain of the first switching transistor. When the first primary voltage electrode of the first switching transistor is the source, the first secondary voltage electrode of the first switching transistor is the drain. When the first primary voltage electrode of the first switching transistor is the drain, the first secondary voltage electrode of the first switching transistor is the source.

Similarly, the second switching transistor has the second primary voltage electrode and the second secondary voltage electrode, and each of the second primary voltage electrode and the second secondary voltage electrode may be a source or drain of the second switching transistor. When the second primary voltage electrode of the second switching transistor is the source, the second secondary voltage electrode of the second switching transistor is the drain. When the second primary voltage electrode of the second switching transistor is the drain, the second secondary voltage electrode of the second switching transistor is the source.

For example, the first primary voltage electrode of the first switching transistor can be set to be the source, the first secondary voltage electrode of the first switching transistor can be set to be the drain, the second primary voltage electrode of the second switching transistor can be set to be the source, and the second secondary voltage electrode of the second switching transistor can be set to be the drain.

More specifically, as shown in FIG. 2, switch group S1 as the first switch group includes switching transistor Q1 as the first switching transistor, and switch group S2 as the second switch group includes switching transistor Q2 as the second switching transistor. A source of switching transistor Q1 can be coupled to a source of switching transistor Q2, and channel potential node VS1 as the first channel potential node is formed therebetween. A drain of switching transistor Q1 can be coupled to a positive terminal of the battery module terminal, and input potential node BAT+ as the first input potential node is formed therebetween. A drain of switching transistor Q2 is coupled to a positive terminal of the battery pack system terminal, and output potential node KL30 as the first output potential node is formed therebetween. The abnormality diagnosis for the switching channel in the circuit-breaker can be achieved by detecting respective potentials at channel potential node VS1, input potential node BAT+, and output potential node KL30.

Similarly, switch group S3 as the first switch group includes switching transistor Q3 as the first switching transistor, and switch group S4 as the second switch group includes switching transistor Q4 as the second switching transistor. A source of switching transistor Q3 can be coupled to a source of switching transistor Q4, and channel potential node VS2 as the first channel potential node is formed therebetween. A drain of switching transistor Q3 can be coupled to the positive terminal of the battery module terminal, and input potential node BAT+ as the first input potential node is formed therebetween. A drain of switching transistor Q4 can be coupled to the positive terminal of the battery pack system terminal, and output potential node KL30 as the first output potential node is formed therebetween. The abnormality diagnosis for the switching channel in the circuit-breaker can be achieved by detecting respective potentials at channel potential node VS2, input potential node BAT+, and output potential node KL30.

In order to enhance the overcurrent capability of the circuit-breaker, the number of MOSFETs in each switch group of the circuit-breaker may be increased according to actual requirement. For example, the number of MOSFETs in each of switch groups S1, S2, S3, and S4 in FIG. 2 may be increased to form a circuit-breaker, in which each switch group includes two MOSFETs, as shown in FIG. 3. Thus, when the overcurrent capability of a single MOSFET remains unchanged, the overcurrent capability of the circuit-breaker shown in FIG. 3 is stronger than that of the circuit-breaker shown in FIG. 2.

More specifically, in one or more embodiments of the present disclosure, as shown in FIG. 3, the circuit-breaker includes two switching channels. Each of the first switch group and the second switch group in each switching channel includes a plurality of switching transistors. The circuit-breaker further includes a third drive terminal and a fourth drive terminal. The first switch group includes a plurality of third switching transistors each having a third control electrode coupled to the third drive terminal. The second switch group includes a plurality of fourth switching transistors each having a fourth control electrode coupled to the fourth drive terminal.

Specifically, as shown in FIG. 3, one of the switching channels includes switch group S5 as the first switch group and switch group S6 as the second switch group. Switch group S5 as the first switch group serves as a charge enable MOSFET group, and switch group S6 as the second switch group serves as a discharge enable MOSFET group.

Switch group S5 as the first switch group includes two switching transistors Q5 and Q6 as the third switching transistors. Each of the two switching transistors Q5 and Q6 has a gate, as the third control electrode, coupled to drive terminal GS5 as the third drive terminal. Switch group S6 as the second switch group includes two switching transistors Q7 and Q8 as the fourth switching transistors. Each of the two switching transistors Q7 and Q8 has a gate, as the fourth control electrode, coupled to drive terminal GS6 as the fourth drive terminal.

In application, both of the two switching transistors Q5 and Q6 can be controlled to be turned on or off by changing a level of drive terminal GS5, and both of the two switching transistors Q7 and Q8 can be controlled to be turned on or off by changing a level of drive terminal GS6, thereby controlling the switching channel to be turned on or off.

Similarly, switch group S7 as the first switch group and switch group S8 as the second switch group constitute the other switching channel. Switch group S7 as the first switch group has the same function as switch group S5 as the first switch group, and switch group S8 as the second switch group has the same function as switch group S6 as the second switch group. That is, switch group S7 serves as a charge enable MOSFET group, and switch group S8 serves as a discharge enable MOSFET group.

Switch group S7 as the first switch group includes two switching transistors Q9 and Q10 as the third switching transistors. Each of the two switching transistors Q9 and Q10 has a gate, as the third control electrode, coupled to drive terminal GS7 as the third drive terminal. Switch group S8 as the second switch group includes two switching transistors Q11 and Q12 as the fourth switching transistors. Each of the two switching transistors Q11 and Q12 has a gate, as the fourth control electrode, coupled to drive terminal GS8 as the fourth drive terminal.

In application, both of the two switching transistors Q9 and Q10 can be controlled to be turned on or off by changing a level of drive terminal GS7, and both of the two switching transistors Q11 and Q12 can be controlled to be turned on or off by changing a level of drive terminal GS8, thereby controlling the switching channel to be turned on or off.

As described above, each of respective gates of all MOSFETs in switch group S5 is connected to the same drive terminal GS5, so that all the MOSFETs in switch group S5 can be controlled synchronously. The same is true for each of switch groups S6, S7 and S8. Thus, the overcurrent capability of the circuit-breaker can be improved.

In one or more embodiments of the present disclosure, as shown in FIG. 3, each of the third switching transistors has a third primary voltage electrode and a third secondary voltage electrode, and each of the fourth switching transistors has a fourth primary voltage electrode and a fourth secondary voltage electrode.

The third primary voltage electrodes of the plurality of third switching transistors are respectively coupled to the fourth primary voltage electrodes of the plurality of fourth switching transistors. A plurality of connection nodes formed respectively between the plurality of third primary voltage electrodes and the plurality of fourth primary voltage electrodes constitute a plurality of second channel potential nodes and are wiredly coupled. Any of the second channel potential nodes can serve as the channel potential node. Each of the respective third secondary voltage electrodes of the plurality of third switching transistors is coupled to the battery module terminal, and a second input potential node as the input potential node is formed between each of the third secondary voltage electrodes and the battery module terminal. Each of the respective fourth secondary voltage electrodes of the plurality of fourth switching transistors is coupled to the battery pack system terminal, and a second output potential node as the output potential node is formed between each of the fourth secondary voltage electrodes and the battery pack system terminal.

In one or more embodiments, each third switching transistor has the third primary voltage electrode and the third secondary voltage electrode, and each of the third primary voltage electrode and the third secondary voltage electrode may be a source or drain of the third switching transistor. When the third primary voltage electrode of the third switching transistor is the source, the third secondary voltage electrode of the third switching transistor is the drain. When the third primary voltage electrode of the third switching transistor is the drain, the third secondary voltage electrode of the third switching transistor is the source.

Similarly, each fourth switching transistor has the fourth primary voltage electrode and the fourth secondary voltage electrode, and each of the fourth primary voltage electrode and the fourth secondary voltage electrode may be a source or drain of the fourth switching transistor. When the fourth primary voltage electrode of the fourth switching transistor is the source, the fourth secondary voltage electrode of the fourth switching transistor is the drain. When the fourth primary voltage electrode of the fourth switching transistor is the drain, the fourth secondary voltage electrode of the fourth switching transistor is the source.

For example, the third primary voltage electrode of the third switching transistor can be set to be the source, the third secondary voltage electrode of the third switching transistor can be set to be the drain, the fourth primary voltage electrode of the fourth switching transistor can be set to be the source, and the fourth secondary voltage electrode of the fourth switching transistor can be set to be the drain.

More specifically, as shown in FIG. 3, switch group S5 as the first switch group includes switching transistors Q5 and Q6 as the third switching transistors, and switch group S6 as the second switch group includes switching transistor Q7 and Q8 as the fourth switching transistors. A source of switching transistor Q5 can be coupled to a source of switching transistor Q7, and a first connection node is formed therebetween. A source of switching transistor Q6 can be coupled to a source of switching transistor Q8, and a second connection node is formed therebetween. The first and second connection nodes constitute two second channel potential nodes and are wiredly coupled, and any of the two second channel potential nodes can serve as channel potential node VS3. Each of respective drains of switching transistors Q5 and Q6 can be coupled to the positive terminal of the battery module terminal, and input potential node BAT+ as the second input potential node is formed therebetween. Each of respective drains of switching transistors Q7 and Q8 can be coupled to the positive terminal of the battery pack system terminal, and output potential node KL30 as the second output potential node is formed therebetween. The abnormality diagnosis for the switching channel in the circuit-breaker can be achieved by detecting respective potentials at channel potential node VS3, input potential node BAT+, and output potential node KL30.

Similarly, switch group S7 as the first switch group includes switching transistors Q9 and Q10 as the third switching transistors, and switch group S8 as the second switch group includes switching transistors Q11 and Q12 as the fourth switching transistors. A source of switching transistor Q9 can be coupled to a source of switching transistor Q11, and a third connection node is formed therebetween. A source of switching transistor Q10 can be coupled to a source of switching transistor Q12, and a fourth connection node is formed therebetween. The third and fourth connection nodes constitute two second channel potential nodes and are wiredly coupled, and any of the two second channel potential nodes can serve as channel potential node VS4. Each of respective drains of switching transistors Q9 and Q10 can be coupled to the positive terminal of the battery module terminal, and input potential node BAT+as the second input potential node is formed therebetween. Each of respective drains of switching transistors Q11 and Q12 can be coupled to the positive terminal of the battery pack system terminal, and output potential node KL30 as the second output potential node is formed therebetween. The abnormality diagnosis for the switching channel in the circuit-breaker can be achieved by detecting respective potentials at channel potential node VS4, input potential node BAT+, and output potential node KL30.

In one or more embodiments of the present disclosure, as shown in FIG. 2 and FIG. 3, a sampling resistor Rs is also coupled between the battery module terminal and the battery pack system terminal, and a third output potential node KL31 is formed between the sampling resistor Rs and the battery pack system terminal. Respective potentials of the battery module terminal and the battery pack system terminal may be acquired through the sampling resistor, which facilitates diagnosis of abnormalities of the MOSFETs in the circuit-breaker. In one or more embodiments, the sampling resistor coupled between the battery module terminal and the battery pack system terminal may be replaced by any other load having the same function as the the sampling resistor, such as a wire.

In addition, one or more embodiments of the present disclosure further provide a circuit-breaker abnormality diagnosis method applicable to the circuit-breaker as described above.

Abnormalities of a MOSFET in the circuit-breaker may include the following situations: 1. The MOSFET has an internal short-circuit and thus cannot be controlled to be turned off; 2. The MOSFET has an internal circuit break and thus cannot be controlled to be turned on; and 3. The MOSFET is aged and thus will have a high on-resistance after controlled to be turned on, which may present a fault similar to that in Situation 2.

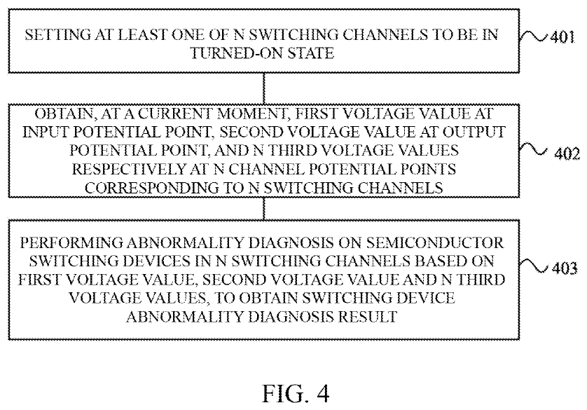

As shown in FIG. 4, the circuit-breaker abnormality diagnosis method may include steps 401 to 403.

In step 401, at least one of the N switching channels is set to be in a turned-on state.

During the diagnosis process, when abnormality diagnosis is performed on one of the N switching channels in the circuit-breaker, the other (N−1) switching channels may maintain in the turned-on state, so as to keep the circuit-breaker in the turned-on state and avoid frequently switching the circuit-breaker to the turned-off state for diagnosis of the circuit-breaker, thereby keeping the circuit-breaker in normal use for a long time.

In step 402, a first voltage value at the input potential node, a second voltage value at the output potential node, and N third voltage values respectively at N channel potential nodes of the N switching channels are obtained at a current moment.

In step 403, abnormality diagnosis is performed on semiconductor switching devices in the N switching channels based on the first voltage value, the second voltage value, and the N third voltage values, to obtain a switching device abnormality diagnosis result.

During the diagnosis process, since the circuit-breaker is always in the turned-on state, a voltage value at the input potential node, a voltage value at the output potential node, and voltage values respectively at N channel potential nodes of the N switching channels can be obtained at the current moment, and it can be determined, based on these voltage values, which switch group in the N switching channels or which semiconductor switching device in the N switching channels may be abnormal.

In one or more embodiments of the present disclosure, all the switching transistors in the switching channels are MOSFETs. Thus, a controlled state of each MOSFET in the switching channels may be identified by obtaining the voltage values respectively at the input potential node, the output potential node and N channel potential nodes of the circuit-breaker, so as to determine which MOSFET may be abnormal.

Several example situations in which there is an abnormality in the N switching channels will be described below in detail.

In one or more embodiments of the present disclosure, each of the N switching channels is set to be in the turned-on state. Then, if the second voltage value is not greater than 0 V, it can be determined as the switching device abnormality diagnosis result that all the semiconductor switching devices in the N switching channels are abnormal. If the second voltage value is greater than 0 V, an i^{th} third voltage value corresponding to an i^{th} switching channel is zero, where i is a positive integer less than N, and each of (N−1) third voltage values respectively corresponding to the remaining (N−1) switching channels is equal to the first voltage value, it can be determined as the switching device abnormality diagnosis result that a part of the semiconductor switching devices in the i^{th} switching channel are abnormal. If the second voltage value is greater than 0 V, and each of the N third voltage values respectively corresponding to the N switching channels is equal to the first voltage value, it can be determined as the switching device abnormality diagnosis result that there is no definite diagnosis result yet.

Specifically, when each of the N switching channels is in the turned-on state, that is, when the circuit-breaker is in the turned-on state: if the potential at the output potential node at the current moment is not greater than 0 V, it can be determined that none of the MOSFETs in the N switching channels is normally turned on, that is, each of the MOSFETs in the N switching channels is abnormal; if the potential at the output potential node at the current moment is greater than 0 V, the third voltage value corresponding to at least one of the N switching channels is zero, and each of the third voltage values respectively corresponding to the remaining switching channels is equal to the first voltage value, it can be determined that a part of the semiconductor switching devices in the at least one of the N switching channels are not normally turned on, that is, a part of the semiconductor switching devices in the at least one of the switching channels cannot be controlled to be normally turned on or is significantly aged; and if the potential at the output potential node at the current moment is greater than 0 V, and each of the N third voltage values respectively corresponding to the N switching channels is equal to the first voltage value, it is possible that none of the semiconductor switching devices in the N switching channels is abnormal or at least one of the semiconductor switching devices in the N switching channels has an abnormality of being short-circuited, that is, a specific abnormality condition of the semiconductor switching devices in the N switching channels cannot be determined, and further checking is required.

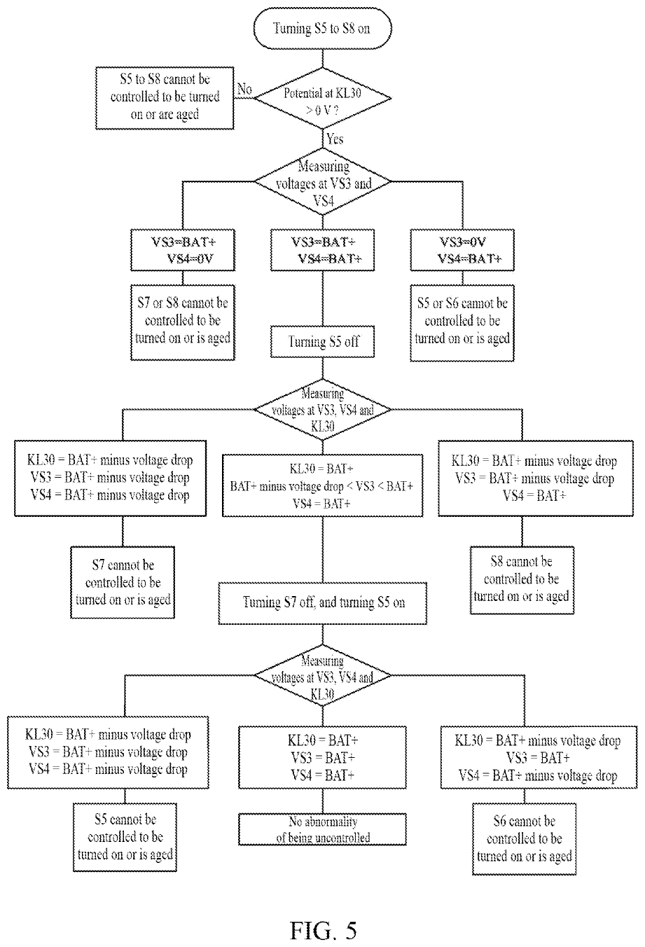

For example, as shown in FIG. 3 and FIG. 5, when N=2 and the two switching channels are both in the turned-on state: if the potential at output potential node KL30 is not greater than 0 V, it can be directly determined that both of the switching channels are abnormal; if the potential at output potential node KL30 is greater than 0 V, a voltage value at one of two channel potential nodes VS3 and VS4 is zero, and a voltage value at the other of the two channel potential nodes VS3 and VS4 is equal to a voltage value at input potential node BAT+, it can be determined that a part of the MOSFETs in a corresponding one of the two switching channels are abnormal; and, however, if the potential at output potential node KL30 is greater than 0 V, and each of voltage values respectively at the two channel potential nodes VS3 and VS4 is equal to the voltage value at the input potential node BAT+, it cannot be determined whether the two switching channels have abnormalities.

In one or more embodiments of the present disclosure, when it is determined as the switching device abnormality diagnosis result that there is no definite diagnosis result yet, the first switch group in a j^{th} switching channel of the N switching channels is set to be in the turned-off state, where j is a positive integer less than N, and each of the remaining (N−1) switching channels is set to be in the turned-on state. Then, if each of a j^{th} third voltage value corresponding to the j^{th} switching channel, the remaining (N−1) third voltage values, and the second voltage value is equal to the first voltage value minus a preset voltage drop value, it can be determined as the switching device abnormality diagnosis result that each of the first switch groups respectively in the remaining (N−1) switching channels is abnormal. If each of the j^{th} third voltage value and the second voltage value is equal to the first voltage value minus the preset voltage drop value, and each of the remaining (N−1) third voltage values is equal to the first voltage value, it can be determined as the switching device abnormality diagnosis result that each of the second switch groups respectively in the remaining (N−1) switching channels is abnormal. If the j^{th} third voltage value is greater than the first voltage value minus the preset voltage drop value and less than the first voltage value, and each of the remaining (N−1) third voltage values and the second voltage value is equal to the first voltage value, it can be determined as the switching device abnormality diagnosis result that none of the semiconductor switching devices in the remaining (N−1) switching channels is abnormal.

For example, as shown in FIG. 3 and FIG. 5, when N=2 and the two switching channels are both in the turned-on state, if the potential at output potential node KL30 is greater than 0 V, and each of the voltage values respectively at the two channel potential nodes VS3 and VS4 is equal to the voltage value at the input potential node BAT+, so that it cannot be determined whether the two switching channels are abnormal, switch group S5 as the first switch group (including MOSFETs Q5 and Q6) in the switching channel corresponding to the channel potential node VS3 may be set to be in the turned-off state, and the switching channel corresponding to the channel potential node VS4 may be set to be in the turned-on state. Then, if each of the voltage values respectively at nodes VS3, VS4 and KL30 is equal to the voltage value at node BAT+minus the preset voltage drop value, since switch group S5 in the switching channel corresponding to node VS3 is in the turned-off state and the potential at node VS4 is equal to that at node KL30, it can be determined that switch group S7 (including MOSFETs Q9 and Q10) in the switching channel corresponding to the channel potential node VS4 cannot be controlled to be normally turned on or is significantly aged. If each of the voltage values respectively at nodes VS3 and KL30 is equal to the voltage value at node BAT+ minus the preset voltage drop value, and the voltage value at node VS4 is equal to the voltage value at node BAT+, since the potential at node VS4 is not equal to that at node KL30, it can be determined that switch group S8 as the second switch group in the switching channel corresponding to the channel potential node VS4 is not turned on, that is, switch group S8 (including MOSFETs Q11 and Q12) cannot be controlled to be normally turned on or is significantly aged. If the voltage value at node VS3 is greater than the voltage value at node BAT+ minus the preset voltage drop value and less than the voltage value at node BAT+, and each of the voltage values respectively at nodes VS4 and KL30 is equal to the voltage value at node BAT+, it can be determined that none of the semiconductor switching devices in the switching channel corresponding to node VS4 is abnormal.

In one or more embodiments of the present disclosure, when it is determined as the switching device abnormality diagnosis result that none of the semiconductor switching devices in the remaining (N−1) switching channels is abnormal, the first switch group in the j^{th} switching channel is set to be in the turned-on state, and each of the first switch groups respectively in the remaining (N−1) switching channels is set to be in the turned-off state. Then, if each of the j^{th} third voltage value corresponding to the j^{th} switching channel, the remaining (N−1) third voltage values, and the second voltage value is equal to the first voltage value minus the preset voltage drop value, it can be determined as the switching device abnormality diagnosis result that the first switch group in the j^{th} switching channel is abnormal. If the j^{th} third voltage value is equal to the first voltage value, and each of the second voltage value and the remaining (N−1) third voltage values is equal to the first voltage value minus the preset voltage drop value, it can be determined as the switching device abnormality diagnosis result that the second switch group in the j^{th} switching channel is abnormal. If each of the j^{th} third voltage value, the remaining (N−1) third voltage values, and the second voltage value is equal to the first voltage value, it can be determined as the switching device abnormality diagnosis result that none of the semiconductor switching devices in the j^{th} switching channel is abnormal, that is, none of the semiconductor switching devices in the N switching channels is abnormal. Thus, further diagnosis of the j^{th} switching channel can be implemented.

For example, as shown in FIG. 3 and FIG. 5, when N=2, switch group S5 as the first switch group (including MOSFETs Q5 and Q6) in the switching channel corresponding to the channel potential node VS3 is set to be in the turned-off state, and the switching channel corresponding to the channel potential node VS4 is set to be in the turned-on state, if it is determined that none of the semiconductor switching devices in the switching channel corresponding to the channel potential node VS4 is abnormal, but it cannot be determined whether the switching channel corresponding to the channel potential node VS3 is abnormal, switch group S5 as the first switch group (including MOSFETs Q5 and Q6) in the switching channel corresponding to the channel potential node VS3 may be set to be in the turned-on state, that is, the switching channel corresponding to the channel potential node VS3 may be turned on, and switch group S7 as the first switch group (including MOSFETs Q9 and Q10) in the switching channel corresponding to the channel potential node VS4 may be set to be in the turned-off state. Then, if each of the voltage values respectively at nodes VS3, VS4 and KL30 is equal to the voltage value at node BAT+ minus the preset voltage drop value, since switch group S7 in the switching channel corresponding to node VS4 is in the turned-off state and the potential at node VS3 is equal to that at node KL30, it can be determined that switch group S5 (including MOSFETs Q5 and Q6) in the switching channel corresponding to the channel potential node VS3 cannot be controlled to be normally turned on or is significantly aged. If the voltage value at node VS3 is equal to the voltage value at node BAT+, and each of the voltage values respectively at nodes VS4 and KL30 is equal to the voltage value at node BAT+ minus the preset voltage drop value, since the potential at node VS3 is not equal to that at node KL30, it can be determined that switch group S6 as the second switch group in the switching channel corresponding to the channel potential node VS3 is not turned on, that is, switch group S6 (including MOSFETs Q7 and Q8) cannot be controlled to be normally turned on or is significantly aged. If each of the voltage values respectively at nodes VS3, VS4 and KL30 is equal to the voltage value at node BAT+, it can be determined that none of the semiconductor switching devices in the switching channel corresponding to the channel potential node VS3 is abnormal.

In one or more embodiments of the present disclosure, when it is determined as the switching device abnormality diagnosis result that there is no definite diagnosis result yet, the second switch group in a k^{th} switching channel of the N switching channels is set to be in the turned-off state, and each of the remaining (N−1) switching channels is set to be in the turned-on state, where k is a positive integer less than N. Then, if a k^{th} third voltage value corresponding to the k^{th} switching channel is equal to the first voltage value, and each of the second voltage value and the remaining (N−1) third voltage values is equal to the first voltage value minus the preset voltage drop value, it can be determined as the switching device abnormality diagnosis result that each of the first switch groups respectively in the remaining (N−1) switching channels is abnormal. If each of the k^{th} third voltage value and the remaining (N−1) third voltage values is equal to the first voltage value, and the second voltage value is equal to the first voltage value minus the preset voltage drop value, it can be determined as the switching device abnormality diagnosis result that each of the second switch groups respectively in the remaining (N−1) switching channels is abnormal. If each of the k^{th} third voltage value, the remaining (N−1) third voltage values, and the second voltage value is equal to the first voltage value, it can be determined as the switching device abnormality diagnosis result that none of the semiconductor switching devices in the remaining (N−1) switching channels is abnormal.

In one or more embodiments of the present disclosure, when it is determined as the switching device abnormality diagnosis result that none of the semiconductor switching devices in the remaining (N−1) switching channels is abnormal, the second switch group in the k^{th} switching channel is set to be in the turned-on state, and each of the second switch groups respectively in the remaining (N−1) switching channels is set to be in the turned-off state. Then, if each of the k^{th} third voltage value corresponding to the k^{th} switching channel and the second voltage value is equal to the first voltage value minus the preset voltage drop value, and each of the remaining (N−1) third voltage values is equal to the first voltage value, it can be determined as the switching device abnormality diagnosis result that the first switch group in the k^{th} switching channel is abnormal. If each of the k^{th} third voltage value and the remaining (N−1) third voltage values is equal to the first voltage value, and the second voltage value is equal to the first voltage value minus the preset voltage drop value, it can be determined as the switching device abnormality diagnosis result that the second switch group in the k^{th} switching channel is abnormal. If each of the k^{th} third voltage value, the remaining (N−1) third voltage values, and the second voltage value is equal to the first voltage value, it can be determined as the switching device abnormality diagnosis result that none of the semiconductor switching devices in the k^{th} switching channel is abnormal, that is, none of the semiconductor switching devices in the N switching channels is abnormal. Thus, further diagnosis of the k^{th} switching channel can be implemented.

In one or more embodiments of the present disclosure, the switching device abnormality diagnosis result includes a short-circuit abnormality diagnosis result, and each of the first switch group and the second switch group in an m^{th} switching channel of the N switching channels is set to be in the turned-off state and each of the remaining (N−1) switching channels is set to be in the turned-on state. Then, if an m^{th} third voltage value corresponding to the m^{th} switching channel is zero, and each of the remaining (N−1) third voltage values and the second voltage value is equal to the first voltage value, it can be determined as the short-circuit abnormality diagnosis result that neither of the first switch group and the second switch group in the m^{th} switching channel has an abnormality of being short-circuited. If each of the m^{th} third voltage value, the remaining (N−1) third voltage values, and the second voltage value is equal to the first voltage value, it can be determined as the short-circuit abnormality diagnosis result that at least one of the first switch group or the second switch group in the m^{th} switching channel has an abnormality of being short-circuited. Here, m may be any positive integer less than N, and in the above manner it can be determined whether each of the N switching channels has an abnormality of being short-circuited.

As an example, diagnosis logic for MOSFETs when the battery pack is not charged by any external charging device and is in a discharge operation condition will be described below in detail with reference to FIG. 3 and FIG. 5. Here, a 12 V vehicle battery pack is taken as an example, and an operation condition, where the vehicle is powered off, a 12 V power network charger has stopped charging the battery pack, and a load on the 12 V power network is completely powered by the battery pack, is assumed. The diagnosis logic may include the first step to the eleventh step.

In the first step, each MOSFET is set, by a controller, to be in a turned-on state, that is, each of drive terminals GS5, GS6, GS7, and GS8 is pulled to a high level.

In the second step, it is determined whether a voltage at node KL30 is greater than 0 V and a discharge current of the battery pack is greater than 0 A or not. If yes, the diagnosis logic proceeds to the third step. If no, it can be determined that each MOSFET cannot be controlled to be turned on or is significantly aged, and thus is in a high impedance state, a fault alarm is generated, and the diagnosis logic is exited.

In the third step, voltage values respectively at nodes VS3, VS4 and BAT+ are measured.

In the fourth step, if voltage value at node VS3 is equal to voltage value at node BAT+ and voltage value at node VS4 is equal to 0 V, it can be determined that each of switch groups S7 & S8 cannot be controlled to be turned on or is significantly aged, and thus is in a high impedance state, a fault alarm is generated, and the diagnosis logic is exited. If voltage value at node VS3 is equal to 0 V and voltage value at node VS4 is equal to voltage value at node BAT+, it can be determined that each of switch groups S5 & S6 cannot be controlled to be turned on or is significantly aged, and thus is in a high impedance state, a fault alarm is generated, and the diagnosis logic is exited. If each of voltage values respectively at nodes VS3 & VS4 is equal to voltage value at node BAT+, the diagnosis logic proceeds to the fifth step.

In the fifth step, switch group S5 is turned off, that is, a low level signal is input to drive terminal GS5, and voltage values respectively at nodes KL30, VS3, and VS4 are acquired.

In the sixth step, if each of voltage values respectively at nodes KL30, VS3, and VS4 is equal to voltage value at node BAT+ minus 0.7 V, it can be determined that switch group S7 cannot be controlled to be turned on or is significantly aged, and thus is in a high impedance state, a fault alarm is generated, and the diagnosis logic is exited. If each of voltage values respectively at nodes KL30 and VS3 is equal to voltage value at node BAT+ minus 0.7 V, and voltage value at node VS4 is equal to voltage value at node BAT+, it can be determined that switch group S8 cannot be controlled to be turned on or is significantly aged, and thus is in a high impedance state, a fault alarm is generated, and the diagnosis logic is exited. If each of voltage values respectively at nodes KL30 and VS4 is equal to voltage value at node BAT+, and voltage value at node VS3 is greater than voltage value at node BAT+ minus 0.7 V and less than voltage value at node BAT+, switch group S5 is turned on, switch group S7 is turned off, and the diagnosis logic proceeds to the seventh step.

In the seventh step, voltage values respectively at nodes KL30, VS3, and VS4 are measured.

In the eighth step, if each of voltage values respectively at nodes VS3, VS4 and KL30 is equal to voltage value at node BAT+ minus 0.7 V, it can be determined that switch group S5 cannot be controlled to be turned on or is significantly aged, and thus is in a high impedance state, a fault alarm is generated, and the diagnosis logic is exited. If each of voltage values respectively at nodes KL30 and VS4 is equal to voltage value at node BAT+ minus 0.7 V, and voltage value at node VS3 is equal to voltage value at node BAT+, it can be determined that switch group S6 cannot be controlled to be turned on or is significantly aged, and thus is in a high impedance state, a fault alarm is generated, and the diagnosis logic is exited. If each of voltage values respectively at nodes KL30, VS3 and VS4 is equal to voltage value at node BAT+, it can be determined that each of switch groups S5, S6, S7, and S8 can be controlled to be turned on.

In the ninth step, the diagnosis logic exits the process of diagnosing an abnormality that the MOSFET cannot be controlled to be turned on, and enters a process of diagnosing an internal short-circuit of the MOSFET (that the MOSFET cannot be controlled to be turned off).

In the tenth step, each of switch groups S5 and S6 is turned off and each of switch groups S7 and S8 is turned on, that is, a low level signal is input to each of drive terminals GS5 and GS6 and a high level signal is input to each of drive terminals GS7 and GS8. Voltage values respectively at nodes VS3, VS4, BAT+, and KL30 are acquired. If voltage value at node VS3 is equal to 0 V, and each of voltage values respectively at nodes VS4 and KL30 is equal to voltage value at node BAT+, it can be determined that each of switch groups S5 and S6 can be controlled to be turned off. If each of voltage values respectively at nodes VS3, VS4 and KL30 is equal to voltage value at node BAT+, it can be determined that at least one of switch group S5 or switch group S6 has an internal short-circuit and cannot be controlled to be turned off, a fault alarm is generated, and the diagnosis logic is exited.

In the eleventh step, each of switch groups S5 and S6 is turned on and each of switch groups S7 and S8 is turned off, that is, a high level signal is input to each of drive terminals GS5 and GS6 and a low level signal is input to each of drive terminals GS7 and GS8. Voltage values respectively at nodes VS3, VS4, BAT+, and KL30 are acquired. If voltage value at node VS4 is equal to 0 V, and each of voltage values respectively at nodes VS3 and KL30 is equal to voltage value at node BAT+, it can be determined that each of switch groups S7 and S8 can be controlled to be turned off. If each of voltage values respectively at nodes VS3, VS4 and KL30 is equal to voltage value at node BAT+, it can be determined that at least one of switch group S7 or switch group S8 has an internal short-circuit and cannot be controlled to be turned off, a fault alarm is generated, and the diagnosis logic is exited.

As described above, according to one or more embodiments of the present disclosure, when the N switching channels are checked for an abnormality of being uncontrolled and a short-circuit abnormality, the circuit-breaker can be kept in a turned-on state by controlling at least one of the N switching channels to be in the turned-on state. When the circuit-breaker is applied to a vehicle-mounted low-voltage power supply, it can be ensured that a battery pack is always connected to a vehicle-mounted low-voltage power supply network, so that abnormality diagnosis can be performed on switching channels of the circuit-breaker to determine a semiconductor switching device in the switching channels with an abnormality of aging or being uncontrolled, thereby allowing for timely detection and diagnosis of a fault and having higher safety.

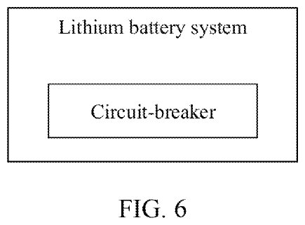

In one or more embodiments of the present disclosure, a lithium battery system including the circuit-breaker as described above is further provided, as shown in FIG. 6.

Some embodiments of the present disclosure have been described in detail above. The description of the above embodiments merely aims to help to understand the present disclosure. Many modifications or equivalent substitutions with respect to the embodiments may occur to those of ordinary skill in the art based on the present disclosure. Thus, these modifications or equivalent substitutions shall fall within the scope of the present disclosure.

What is claimed is:

1. A circuit-breaker, comprising:
a battery module terminal and a battery pack system terminal; and
N switching channels connected in parallel and coupled between the battery module terminal and the battery pack system terminal, where N is a positive integer greater than or equal to 2, each of the switching channels comprising one or more semiconductor switching devices and being configured to turn on/off a circuit between the battery module terminal and the battery pack system terminal,
wherein when abnormality diagnosis is performed on the N switching channels, at least one of the N switching channels is set to be in a turned-on state to keep the circuit-breaker in a turned-on state.

2. The circuit-breaker according to claim 1, wherein each of the switching channels comprises:
a first switch group coupled to the battery module terminal; and
a second switch group coupled to the first switch group and the battery pack system terminal,
wherein a coupling node between the first switch group and the second switch group serves as a channel potential node, an input potential node is formed between the first switch group and the battery module terminal, and an output potential node is formed between the second switch group and the battery pack system terminal.

3. The circuit-breaker according to claim 2, further comprising a first drive terminal and a second drive terminal,
wherein the first switch group comprises a first switching transistor having a first control electrode coupled to the first drive terminal; and
the second switch group comprises a second switching transistor having a second control electrode coupled to the second drive terminal.

4. The circuit-breaker according to claim 3, wherein the first switching transistor has a first primary voltage electrode and a first secondary voltage electrode, and the second switching transistor has a second primary voltage electrode and a second secondary voltage electrode;
the first primary voltage electrode is coupled to the second primary voltage electrode, and a first channel potential node as the channel potential node is formed between the first primary voltage electrode and the second primary voltage electrode;
the first secondary voltage electrode is coupled to the battery module terminal, and a first input potential node as the input potential node is formed between the first secondary voltage electrode and the battery module terminal; and
the second secondary voltage electrode is coupled to the battery pack system terminal, and a first output potential node as the output potential node is formed between the second secondary voltage electrode and the battery pack system terminal.

5. The circuit-breaker according to claim 2, further comprising a third drive terminal and a fourth drive terminal,
wherein the first switch group comprises a plurality of third switching transistors each having a third control electrode coupled to the third drive terminal; and
the second switch group comprises a plurality of fourth switching transistors each having a fourth control electrode coupled to the fourth drive terminal.

6. The circuit-breaker according to claim 5, wherein the third switching transistors have third primary voltage electrodes respectively and have third secondary voltage electrodes respectively, and the fourth switching transistors have fourth primary voltage electrodes respectively and have fourth secondary voltage electrodes respectively;
the third primary voltage electrodes are respectively coupled to the fourth primary voltage electrodes, a plurality of connection nodes formed respectively between the third primary voltage electrodes and the fourth primary voltage electrodes constitute a plurality of second channel potential nodes and are wiredly coupled, and any of the second channel potential nodes serves as the channel potential node;
each of the third secondary voltage electrodes is coupled to the battery module terminal, and a second input potential node as the input potential node is formed between the each of the third secondary voltage electrodes and the battery module terminal; and
each of the fourth secondary voltage electrodes is coupled to the battery pack system terminal, and a second output potential node as the output potential node is formed between the each of the fourth secondary voltage electrodes and the battery pack system terminal.

7. The circuit-breaker according to claim 1, further comprising a sampling resistor coupled between the battery module terminal and the battery pack system terminal.

8. A circuit-breaker abnormality diagnosis method, applicable to a circuit-breaker comprising:
a battery module terminal and a battery pack system terminal; and
N switching channels connected in parallel and coupled between the battery module terminal and the battery pack system terminal, where N is a positive integer greater than or equal to 2, each of the switching channels comprising a plurality of semiconductor switching devices and being configured to turn on/off a circuit between the battery module terminal and the battery pack system terminal,
wherein each of the switching channels comprises: a first switch group coupled to the battery module terminal; and a second switch group coupled to the first switch group and the battery pack system terminal, wherein an input potential node is formed between the first switch group and the battery module terminal, an output potential node is formed between the second switch group and the battery pack system terminal, and a coupling node between the first switch group and the second switch group serves as a channel potential node so that N channel potential nodes respectively corresponding to the N switching channels are formed; and
the circuit-breaker abnormality diagnosis method comprises:
setting at least one of the N switching channels to be in a turned-on state;
obtaining, at a current moment, a first voltage value at the input potential node, a second voltage value at the output potential node, and N third voltage values respectively at the N channel potential nodes; and
performing abnormality diagnosis on the semiconductor switching devices in the N switching channels based on the first voltage value, the second voltage value and the N third voltage values, to obtain a switching device abnormality diagnosis result.

9. The circuit-breaker abnormality diagnosis method according to claim 8, wherein the switching device abnormality diagnosis result comprises a diagnosis result for an abnormality of being uncontrolled; and
the performing of the abnormality diagnosis on the semiconductor switching devices in the N switching channels to obtain the switching device abnormality diagnosis result comprises:
setting each of the N switching channels to be in the turned-on state; and
one of:
in response to determining that the second voltage value is not greater than 0 V, determining as the diagnosis result for the abnormality of being uncontrolled that each of the semiconductor switching devices in the N switching channels has the abnormality of being uncontrolled;
in response to determining that the second voltage value is greater than 0 V, an i^{th} third voltage value of the N third voltage values corresponding to an i^{th} switching channel of the N switching channels is zero, where i is a positive integer less than N, and each of (N−1) third voltage values of the N third voltage values respectively corresponding to (N−1) switching channels of the N switching channels other than the i^{th} switching channel is equal to the first voltage value, determining as the diagnosis result for the abnormality of being uncontrolled that a part of the semiconductor switching devices in the i^{th} switching channel have the abnormality of being uncontrolled; and
in response to determining that the second voltage value is greater than 0 V, and each of the N third voltage values is equal to the first voltage value, determining as the diagnosis result for the abnormality of being uncontrolled that there is no definite diagnosis result yet.

10. The circuit-breaker abnormality diagnosis method according to claim 9, wherein the performing of the abnormality diagnosis on the semiconductor switching devices in the N switching channels to obtain the switching device abnormality diagnosis result further comprises:
in response to determining as the diagnosis result for the abnormality of being uncontrolled that there is no definite diagnosis result yet, setting the first switch group in a j^{th} switching channel of the N switching channels to be in a turned-off state, where j is a positive integer less than N, and setting each of (N−1) switching channels of the N switching channels other than the j^{th} switching channel to be in the turned-on state; and
one of:
in response to determining that each of a j^{th} third voltage value of the N third voltage values corresponding to the j^{th} switching channel, (N−1) third voltage values of the N third voltage values other than the j^{th} third voltage value, and the second voltage value is equal to the first voltage value minus a preset voltage drop value, determining as the diagnosis result for the abnormality of being uncontrolled that the first switch group in each of the (N−1) switching channels other than the j^{th} switching channel has the abnormality of being uncontrolled;
in response to determining that each of the j^{th} third voltage value and the second voltage value is equal to the first voltage value minus the preset voltage drop value, and each of the (N−1) third voltage values other than the j^{th} third voltage value is equal to the first voltage value, determining as the diagnosis result for the abnormality of being uncontrolled that the second switch group in each of the (N−1) switching channels other than the j^{th} switching channel has the abnormality of being uncontrolled; and
in response to determining that the j^{th} third voltage value is greater than the first voltage value minus the preset voltage drop value and less than the first voltage value, and each of the (N−1) third voltage values other than the j^{th} third voltage value and the second voltage value is equal to the first voltage value, determining as the diagnosis result for the abnormality of being uncontrolled that none of the semiconductor switching devices in the (N−1) switching channels other than the j^{th} switching channel has the abnormality of being uncontrolled.

11. The circuit-breaker abnormality diagnosis method according to claim 10, wherein the performing of the abnormality diagnosis on the semiconductor switching devices in the N switching channels to obtain the switching device abnormality diagnosis result further comprises:
in response to determining as the diagnosis result for the abnormality of being uncontrolled that none of the semiconductor switching devices in the (N−1) switching channels other than the j^{th} switching channel has the abnormality of being uncontrolled, setting the first switch group in the j^{th} switching channel to be in the turned-on state, and setting the first switch group in each of the (N−1) switching channels other than the j^{th} switching channel to be in the turned-off state; and
one of:
in response to determining that each of the j^{th} third voltage value, the (N−1) third voltage values other than the j^{th} third voltage value, and the second voltage value is equal to the first voltage value minus the preset voltage drop value, determining as the diagnosis result for the abnormality of being uncontrolled that the first switch group in the j^{th} switching channel has the abnormality of being uncontrolled;
in response to determining that the j^{th} third voltage value is equal to the first voltage value, and each of the second voltage value and the (N−1) third voltage values other than the j^{th} third voltage value is equal to the first voltage value minus the preset voltage drop value, determining as the diagnosis result for the abnormality of being uncontrolled that the second switch group in the j^{th} switching channel has the abnormality of being uncontrolled; and
in response to determining that each of the j^{th} third voltage value, the (N−1) third voltage values other than the j^{th} third voltage value, and the second voltage value is equal to the first voltage value, determining as the diagnosis result for the abnormality of being uncontrolled that none of the semiconductor switching devices in the j^{th} switching channel has the abnormality of being uncontrolled.

12. The circuit-breaker abnormality diagnosis method according to claim 9, wherein the performing of the abnormality diagnosis on the semiconductor switching devices in the N switching channels to obtain the switching device abnormality diagnosis result further comprises:
in response to determining as the diagnosis result for the abnormality of being uncontrolled that there is no definite diagnosis result yet, setting the second switch group in a k^{th} switching channel of the N switching channels to be in a turned-off state, where k is a positive integer less than N, and setting each of (N−1) switching channels of the N switching channels other than the k^{th} switching channel to be in the turned-on state; and
one of:
in response to determining that a k^{th} third voltage value of the N third voltage values corresponding to the k^{th} switching channel is equal to the first voltage value, and each of the second voltage value and (N−1) third voltage values of the N third voltage values other than the k^{th} third voltage value is equal to the first voltage value minus a preset voltage drop value, determining as the diagnosis result for the abnormality of being uncontrolled that the first switch groups in each of the (N−1) switching channels other than the k^{th} switching channel has the abnormality of being uncontrolled;
in response to determining that each of the k^{th} third voltage value and the (N−1) third voltage values other than the k^{th} third voltage value is equal to the first voltage value, and the second voltage value is equal to the first voltage value minus the preset voltage drop value, determining as the diagnosis result for the abnormality of being uncontrolled that the second switch group in each of the (N−1) switching channels other than the k^{th} switching channel has the abnormality of being uncontrolled; and
in response to determining that each of the k^{th} third voltage value, the (N−1) third voltage values other than the k^{th} third voltage value, and the second voltage value is equal to the first voltage value, determining as the diagnosis result for the abnormality of being uncontrolled that none of the semiconductor switching devices in the (N−1) switching channels other than the k^{th} switching channel has the abnormality of being uncontrolled.

13. The circuit-breaker abnormality diagnosis method according to claim 12, wherein the performing of the abnormality diagnosis on the semiconductor switching devices in the N switching channels to obtain the switching device abnormality diagnosis result further comprises:
in response to determining as the diagnosis result for the abnormality of being uncontrolled that none of the semiconductor switching devices in the (N−1) switching channels other than the k^{th} switching channel has the abnormality of being uncontrolled, setting the second switch group in the k^{th} switching channel to be in the turned-on state, and setting the second switch group in each of the (N−1) switching channels other than the k^{th} switching channel to be in the turned-off state; and
one of:
in response to determining that each of the k^{th} third voltage value and the second voltage value is equal to the first voltage value minus the preset voltage drop value, and each of the (N−1) third voltage values other than the k^{th} third voltage value is equal to the first voltage value, determining as the diagnosis result for the abnormality of being uncontrolled that the first switch group in the k^{th} switching channel has the abnormality of being uncontrolled;
in response to determining that each of the k^{th} third voltage value and the (N−1) third voltage values other than the k^{th} third voltage value is equal to the first voltage value, and the second voltage value is equal to the first voltage value minus the preset voltage drop value, determining as the diagnosis result for the abnormality of being uncontrolled that the second switch group in the k^{th} switching channel has the abnormality of being uncontrolled; and
in response to determining that each of the k^{th} third voltage value, the (N−1) third voltage values other than the k^{th} third voltage value, and the second voltage value is equal to the first voltage value, determining as the diagnosis result for the abnormality of being uncontrolled that none of the semiconductor switching devices in the k^{th} switching channel has the abnormality of being uncontrolled.

14. The circuit-breaker abnormality diagnosis method according to claim 8, wherein the switching device abnormality diagnosis result comprises a short-circuit abnormality diagnosis result; and
the performing of the abnormality diagnosis on the semiconductor switching devices in the N switching channels to obtain the switching device abnormality diagnosis result comprises:
setting each of the first switch group and the second switch group in an m^{th} switching channel of the N switching channels to be in a turned-off state, and setting each of (N−1) switching channels of the N switching channels other than the m^{th} switching channel to be in the turned-on state; and
one of:
in response to determining that an m^{th} third voltage value of the N third voltage values corresponding to the m^{th} switching channel is zero, and each of (N−1) third voltage values of the N third voltage values other than the m^{th} third voltage value and the second voltage value is equal to the first voltage value, determining as the short-circuit abnormality diagnosis result that neither of the first switch group and the second switch group in the m^{th} switching channel has an abnormality of being short-circuited; and
in response to determining that each of the m^{th} third voltage value, the (N−1) third voltage values other than the m^{th} third voltage value, and the second voltage value is equal to the first voltage value, determining as the short-circuit abnormality diagnosis result that at least one of the first switch group or the second switch group in the m^{th} switching channel has the abnormality of being short-circuited.

15. A lithium battery system, comprising a circuit-breaker,
wherein the circuit-breaker comprises:
a battery module terminal and a battery pack system terminal; and
N switching channels connected in parallel and coupled between the battery module terminal and the battery pack system terminal, where N is a positive integer greater than or equal to 2, each of the switching channels comprising one or more semiconductor switching devices and being configured to turn on/off a circuit between the battery module terminal and the battery pack system terminal,
wherein when abnormality diagnosis is performed on the N switching channels, at least one of the N switching channels is set to be in a turned-on state to keep the circuit-breaker in a turned-on state.

16. The lithium battery system according to claim 15, wherein each of the switching channels comprises:
a first switch group coupled to the battery module terminal; and
a second switch group coupled to the first switch group and the battery pack system terminal,
wherein a coupling node between the first switch group and the second switch group serves as a channel potential node, an input potential node is formed between the first switch group and the battery module terminal, and an output potential node is formed between the second switch group and the battery pack system terminal.

17. The lithium battery system according to claim 16, wherein the circuit-breaker further comprises a first drive terminal and a second drive terminal;
the first switch group comprises a first switching transistor having a first control electrode coupled to the first drive terminal; and
the second switch group comprises a second switching transistor having a second control electrode coupled to the second drive terminal.

18. The lithium battery system according to claim 17, wherein the first switching transistor has a first primary voltage electrode and a first secondary voltage electrode, and the second switching transistor has a second primary voltage electrode and a second secondary voltage electrode;
the first primary voltage electrode is coupled to the second primary voltage electrode, and a first channel potential node as the channel potential node is formed between the first primary voltage electrode and the second primary voltage electrode;
the first secondary voltage electrode is coupled to the battery module terminal, and a first input potential node as the input potential node is formed between the first secondary voltage electrode and the battery module terminal; and
the second secondary voltage electrode is coupled to the battery pack system terminal, and a first output potential node as the output potential node is formed between the second secondary voltage electrode and the battery pack system terminal.

19. The lithium battery system according to claim 16, wherein the circuit-breaker further comprises a third drive terminal and a fourth drive terminal;
the first switch group comprises a plurality of third switching transistors each having a third control electrode coupled to the third drive terminal; and
the second switch group comprises a plurality of fourth switching transistors each having a fourth control electrode coupled to the fourth drive terminal.

20. The lithium battery system according to claim 19, wherein the third switching transistors have third primary voltage electrodes respectively and have third secondary voltage electrodes respectively, and the fourth switching transistors have fourth primary voltage electrodes respectively and have fourth secondary voltage electrodes respectively;
the third primary voltage electrodes are respectively coupled to the fourth primary voltage electrodes, a plurality of connection nodes formed respectively between the third primary voltage electrodes and the fourth primary voltage electrodes constitute a plurality of second channel potential nodes and are wiredly coupled, and any of the second channel potential nodes serves as the channel potential node;
each of the third secondary voltage electrodes is coupled to the battery module terminal, and a second input potential node as the input potential node is formed between the each of the third secondary voltage electrodes and the battery module terminal; and
each of the fourth secondary voltage electrodes is coupled to the battery pack system terminal, and a second output potential node as the output potential node is formed between the each of the fourth secondary voltage electrodes and the battery pack system terminal.
